(19) United States
(12) Patent Application Publication
(10) Pub. No.: US 2013/0153856 A1
(43) Pub. Date: Jun. 20, 2013

(54) INFRARED LED DEVICE WITH ISOLATION AND METHOD OF MAKING

(71) Applicant: Naresh C. Das, Dayton, MD (US)

(72) Inventor: Naresh C. Das, Dayton, MD (US)

(73) Assignee: U.S. Government as represented by the Secretary of the Amry, Adelphi, MD (US)

(21) Appl. No.: 13/327,142

(22) Filed: Dec. 15, 2011

(51) Int. Cl. H01L 33/06; H01L 33/30

(52) U.S. Cl. 257/13; 438/26; 257/E33.005; 257/E33.019

(57) ABSTRACT

An infrared LED device comprising a plurality of LED mesas; each mesa being approximately 25 to 500 microns separated by a gap of approximately 50 to 100 microns; each mesa having at least two indium contacts; a substrate; and a plurality of leads for connection to the contacts, whereby upon application of electrical power infrared light emission occurs. The method of making comprises providing a first substrate; using molecular beam epitaxy, growing a quantum well structure comprising alternating active and injection regions on the substrate; growing a thin p-type layer on the quantum well structure; etching the mesa area down to the substrate to form a plurality of mesas, forming first electrical contacts; deep etching to isolate each of the mesas; depositing first indium contacts on the mesas; providing a second substrate; depositing second electrical contacts; bonding the first and second substrates at the points of the electrical contacts.

### GOVERNMENT INTEREST

The invention described herein may be manufactured, used, and/or licensed by or for the United States Government.

### BACKGROUND OF THE INVENTION

There exists a great deal of interest in using infrared light emitting devices as light sources in IR scene projection experiments. Large format (512×512) silicon nitride resistor arrays from Honeywell Corporation are presently used at the Advanced Simulation Center (ASC) of the Aviation and Missile Research, Engineering and Development Center (AMRDEC) of the US Army Aviation and Missile Command (AMCOM). However, long term reliability and the maximum temperature of emission are still issues for IR resistor technology for HWIL applications. See, for example, D. Brett Beasley, et al., “Overview of dynamic scene projectors at the U.S. Army aviation and missile command,” Proceedings of SPIE, Vol. 4717, p. 136, 2002, hereby incorporated by reference. IR LED arrays provide an extra benefit of fast switching and high emission temperature characteristics, as reported in N. C. Das and M. S. Tobin, “Performance of Mid-wave Infrared (3.8 μm) Light Emitting Diode Device,” Solid state electronics, Vol. 50, p. 1612, 2006. Recently, there has been renewed interest in using IR LED array as a thermal source for IR scene generation experiments. There exist various techniques to improve the extraction of IR light from high index substrate material like GaSb including grating (N. C. Das, Effect of grating on IR LED device performance, Infrared Physics and technology, 53, 71, 2010 (hereby incorporated by reference)), anti reflection coating (R. Windisch et al, Light-emitting Diodes with 31% External Quantum Efficiency by Out coupling of Lateral Waveguide Modes, Applied Physics Letters, 74, 2256 (1999) (hereby incorporated by reference) and slope mesa structure (B. A. Matveev, et al., “Mid-infrared (3-5 μm) LEDs as Sources for gas and Liquid Sensors,” Actuators, B, 38, 339 (1997) (hereby incorporated by reference). However, the output conversion efficiency (ratio of optical power output to electrical power input) of IR LEDs is still low compared to their visible counterparts (See, R Q Yang, et al., “Interband Cascade LED Array with Record High Efficiency,” Appl. Physics Letters, 70, 2013, (1997) (hereby incorporated by reference). Another important limiting factor of the IR LEDs performance is the thermal cross talk between two adjacent pixels, (see, for example, Shatalov, M., et al. “Thermal Analysis of Flip-Chip Packaged 280nm Nitride-Based Deep Ultraviolet Light-Emitting Diodes,” Applied Physics Letters, Vol. 86, 201109, (2005) (hereby incorporated by reference)) since the heat created due to non-radiative recombination can conduct to the adjacent pixel. It is predicted that cross talk can be minimized if the LED pixels can be separated from their common substrate material.

In an article by the inventor entitled “Increase in Midwave Infrared Light Emitting Diode Light Output due to Substrate Thinning and Texturing,” Applied Physics Letters, 90, pages 011111-011111-3 (2007), midwave infrared (MWIR) light sources are disclosed with high optical power (3.8 μm peak) light emission from an interband cascade light emitting diode (LED) structure with 18 cascaded active/injection regions grown on GaSb substrate. The light is emitted from the substrate side of the device. An increase of six times of light output power is observed due to substrate thinning and another 50% increase is observed due to texturing the emission surface. The inventor observed 400 μW emission power for room temperature operation with 15 mA LED injection current. Experiments were carried out with different grating patterns and etch depths. It was determined that the device with a 2 μm square grating and a 1 μm etch depth had the highest optical emission.

### SUMMARY OF THE INVENTION

A preferred design and fabricating method may be utilized in conjunction with a long wave infrared (LWIR) LED devices on n-type GaSb substrate with epi side mounted on a substrate, such as for example, silicon. Shown in FIG. 1 is an device 10′ comprising a silicon fanout substrate 1, indium bumps or contacts 4, mesa or pixel structures 3 and the GaSb substrate 2. It can be appreciated by those of ordinary skill in the art the other materials may be substituted for the silicon substrate, such as, for example, glass without departing from the scope of the invention. For such a substrate, a “fanout array” may be formed using a photolithographic process to form conductive lead lines (or “fanout array”) within the silicon chip in a manner well known to those of ordinary skill in the art. For example, the process may involve the deposition of silicon dioxide, and then, using a photolithographic technique, using a pattern for depositing gold metal to form gold metal lines and pads on the silicon substrate. The indium bumps or contacts 4′ and 4″ are selected due to the softness of the contacts which permit a secure contact when the two substrates 1, 2 are mounted together. As shown in FIGS. 3 and 4, the substrates are initially separate and later joined by joining the Indium bumps or contacts together as shown in FIG. 1. As shown in FIG. 4, the indium contacts are deposited (approximately 5-10 microns) on the upper surface of the gold pads. The fanout silicon substrate 1 (having the indium contacts 4′ as shown in FIG. 4) is bonded to the GaSb mesa structure (substrate 2, mesa 3 and indium contacts 4″, as shown in FIG. 3) such that first indium contacts are in contact with the second indium contacts.

In accordance with the principles of the present invention a preferred embodiment infrared LED device comprises a plurality of LED mesas; each mesa separated by a gap of approximately 50 to 100 microns; each mesa being from approximately 25 to 500 microns, a plurality of indium contacts, each mesa having at least two contacts associated therewith; one positive and one ground contact, a substrate; a plurality of leads for connection to the positive and negative contacts, whereby upon application of electrical power infrared light emission occurs.

The preferred embodiment may be a Type II superlattice which is mounted epi-side down and wherein the mesas are positioned in an array. The Quantum well structure within the mesa 3 comprises alternating cascaded active/injection regions.

A preferred method of making an infrared LED device comprises providing a first substrate; using molecular beam epitaxy, growing a quantum well structure comprising alternating active and injection regions on the substrate; growing a thin p-type layer on the quantum well structure; etching the mesa area down to the substrate to form a plurality of mesas, each mesa being separated by a separation region of approximately 50 to 100 microns; each mesa being from approximately 25 to 500 microns; forming electrical contacts; deep etching to isolate each of the mesas; deposit first indium contacts on the upper surface of the mesas; provide a second substrate; forming electrically conducting lines and pads; depositing second indium contacts on the upper surface of the gold pads; bonding the fanout silicon substrate and the GaSb mesa structure such that first indium contacts are in contact with the second indium contacts.

A preferred embodiment method of making an infrared LED device comprises providing a substrate; using molecular beam epitaxy, growing a quantum well structure comprising alternating active and injection regions on the substrate; growing a thin p-type layer on the quantum well structure; etching the mesa area down to the substrate to form a plurality of mesas, each mesa being separated by a separation region of approximately 50 to 100 microns; each mesa being from approximately 25 to 500 microns; using photolithography to make a pattern for anode and cathode contacts; etching the silicon nitride layer using dry etching; depositing gold metal by electron beam evaporation technique to form the anode and cathode contacts; deep etching (approximately 20 microns) to form a trench around the mesas for mechanical stability to form a GaSb mesa structure; deposit first indium contacts (approximately 5-10 microns) on the upper surface of the mesas; provide a silicon substrate; depositing silicon dioxide on the substrate; using a photolithographic technique, depositing gold metal to form gold metal lines and pads; deposit second indium contacts (approximately 5-10 microns) on the upper surface of the gold pads; flip-chip bonding the fanout silicon substrate and the GaSb mesa structure such that first indium contacts are in contact with the second indium contacts; applying epoxy in the separation regions; curing the epoxy at approximately 70 to 100 degrees Celsius for one to two hours; removing a portion of the GaSb layer (up to approximately 475 microns to leave approximately 25 microns; chemical etching the remaining 25 microns to isolate the mesas.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The present invention can best be understood when reading the following specification with reference to the accompanying drawings, which are incorporated in and form a part of the specification, illustrate alternate embodiments of the present invention, and together with the description, serve to explain the principles of the invention. In the drawings:

FIG. 1A is a schematic diagram of an LED device 10 before substrate thinning and pixel separation.

FIG. 1B is a schematic diagram of an LED device 10 after substrate thinning and pixel separation.

FIG. 2 is a schematic diagram showing, inter alfa, the approximate location of the quantum well structure.

FIG. 3 is an illustration showing an LED mesa (or pixel) with two indium bumps positioned thereon.

FIG. 4 is an illustration showing a test metal pad with two indium bumps.

FIG. 5 is band diagram of the type II interband cascade structure.

FIG. 6 is a photographic illustration of the substrate side of bottom emitting unetched sample.

FIG. 7 is a photographic illustration of the substrate side of bottom emitting sample after etching and device isolation with pixels 3 shown in an array.

FIG. 8 is an SEM picture of a LED mesa and the epoxy near it.

FIG. 9 illustrates the optical output power versus LED injection current (LI) for both the devices of etched and unetched samples.

FIG. 10 is a graphical illustration of current versus voltage for etched and unetched devices.

A more complete appreciation of the invention will be readily obtained by reference to the following Description of the Preferred Embodiments and the accompanying drawings in which like numerals in different figures represent the same structures or elements. The representations in each of the figures are diagrammatic and no attempt is made to indicate actual scales or precise ratios. Proportional relationships are shown as approximates.

### DETAILED DESCRIPTION OF THE PREFERRED EMBODIMENTS

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions may be exaggerated for clarity. Like numbers refer to like elements throughout. As used herein the term “and/or” includes any and all combinations of one or more of the associated listed items.

The terminology used herein is for the purpose of describing particular embodiments only and is not intended to limit the full scope of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. Furthermore, the term “outer” may be used to refer to a surface and/or layer that is farthest away from a substrate.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have tapered, rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will also be appreciated by those of skill in the art that references to a structure or feature that is disposed “adjacent” another feature may have portions that overlap or underlie the adjacent feature.

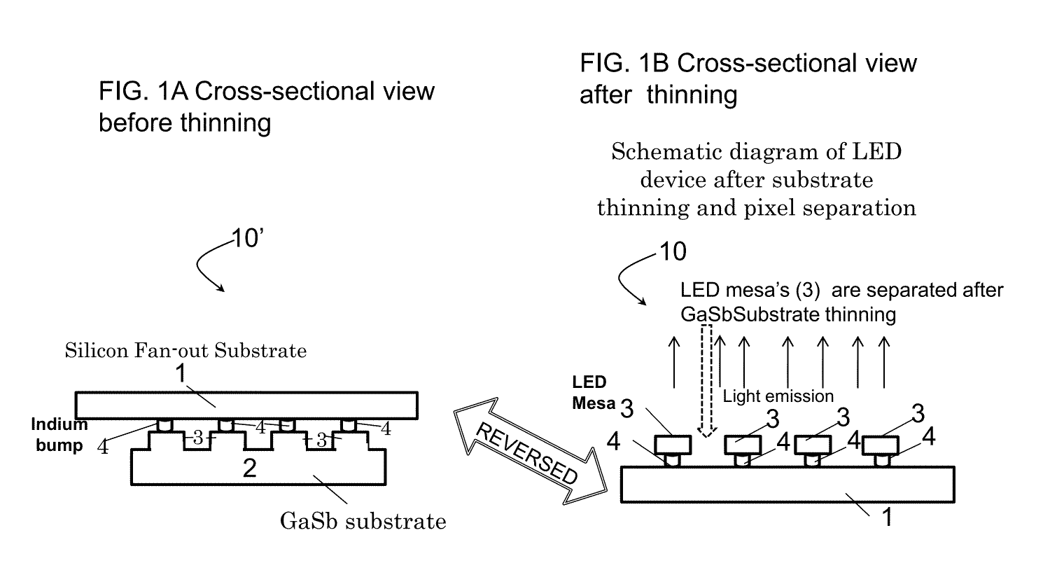

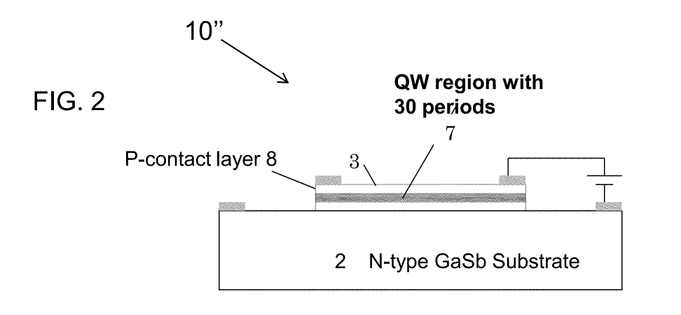

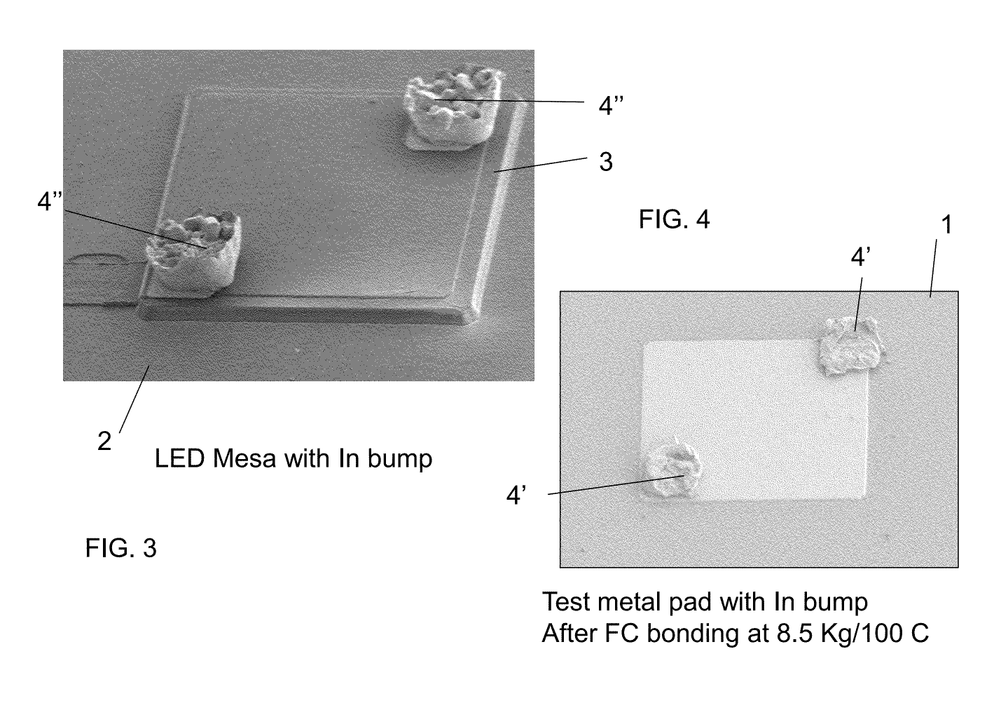

A preferred design and fabricating method may be utilized in conjunction with a long wave infrared (LWIR) LED devices on n-type GaSb substrate with epi side mounted on a substrate, such as for example, silicon. Shown in FIG. 1 is an device 10′ comprising a silicon fanout substrate 1, indium bumps or contacts 4, mesa or pixel structures 3 and the GaSb substrate 2. It can be appreciated by those of ordinary skill in the art the other materials may be substituted for the silicon substrate, such as, for example, glass without departing from the scope of the invention. For such a substrate, a “fanout array” may be formed using a photolithographic process to form conductive lead lines (or “fanout array”) within the silicon chip in a manner well known to those of ordinary skill in the art. For example, the process may involve the deposition of silicon dioxide, and then, using a photolithographic technique, using a pattern for depositing gold metal to form gold metal lines and pads on the silicon substrate. The indium bumps or contacts 4′ and 4″ are selected due to the softness of the contacts which permit a secure contact when the two substrates 1, 2 are mounted together. As shown in FIGS. 3 and 4, the substrates are initially separate and later joined by joining the Indium bumps or contacts together as shown in FIG. 1. As shown in FIG. 4, the indium contacts are deposited (approximately 5-10 microns) on the upper surface of the gold pads. The fanout silicon substrate 1 (having the indium contacts 4′ as shown in FIG. 4) is bonded to the GaSb mesa structure (substrate 2, mesa 3 and indium contacts 4″, as shown in FIG. 3) such that first indium contacts are in contact with the second indium contacts.

The preferred embodiment of the present invention may provide enhancement of LED emission power of up to 300%. The fabrication process involves the thinning of the GaSb substrate and complete isolation of the LED pixels from the substrate. A preferred embodiment GaSb substrate may be thinned by lapping and, if necessary, by wet chemical etching to isolate each LED pixel mesa area. Based upon experimental results and LED device ILV (current-light-voltage) curves and there is about 3-4 times increase in light output by using a preferred embodiment.

A bottom emitting LED may be used; which has a higher optical emission power than the top emitting configuration as reported N. C. Das, Performance comparison of top and bottom emitting LWIR LED devices, J. of Electronic Material, vol. 38, 2329, (2009), hereby incorporated by reference. MESA CONFIGURATION

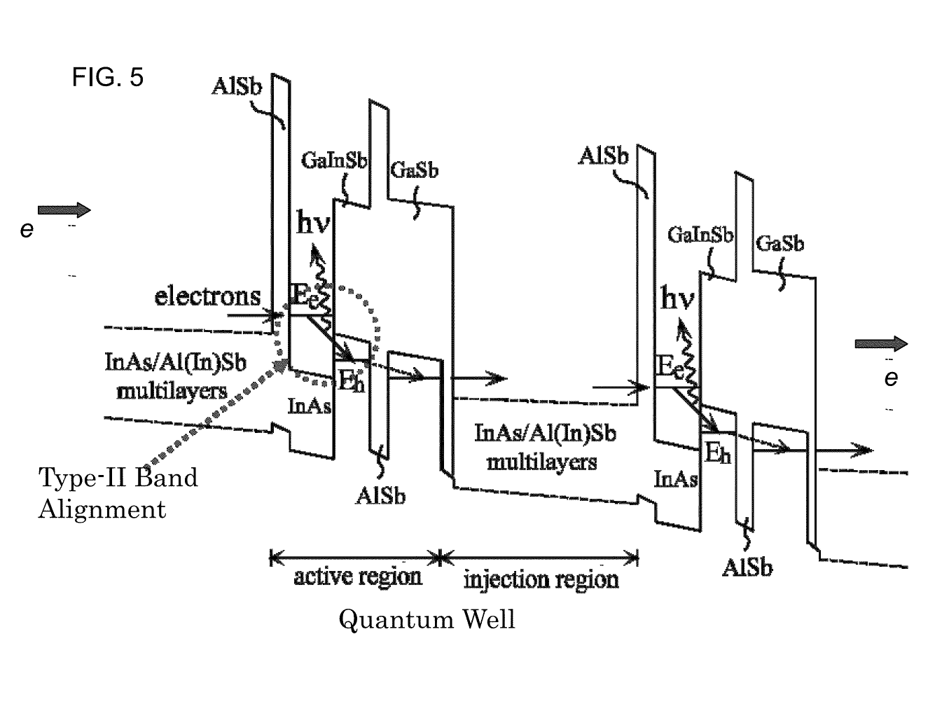

A preferred embodiment IC LED structure was grown by molecular beam epitaxy on an n-type 500 lm-thick GaSb substrate. The total thickness of active and injection regions was 478 A° and it was designed for a peak emission of 8 μm at room temperature. The active region was sandwiched between a 1.4 micron thick top p-type contact layer 8 and a 0.4 micron-thick bottom contact layer 7, consisting of 30 cascaded active/injection periods. The top contact layer 8 of 1.4 microns was used for grating formation to improve the light output efficiency. The schematic diagram of the band diagram of the interband cascade structure is given in FIG. 5. In this epi-structure, each period included an asymmetric InAs/GaInSb/InAs ‘W’ quantum well preceded by an n-type digitally graded InAs/Al(In)Sb injector. The n-type injection region served as the collector and emitter for the preceding and following active regions, respectively. The whole multilayer structure was strain balanced and lattice matched to the GaSb substrate. Under a forward bias, electrons were injected from an injection region into the Eₑ, level which is in the band gap region of the adjacent GaInSb layer. Since the electrons in the Eₑ level are effectively blocked from directly tunneling out of the GaInSb and AlSb layers, they tend to relax to the hole state Eₕ in the adjacent valence band quantum well, resulting in photon emission.

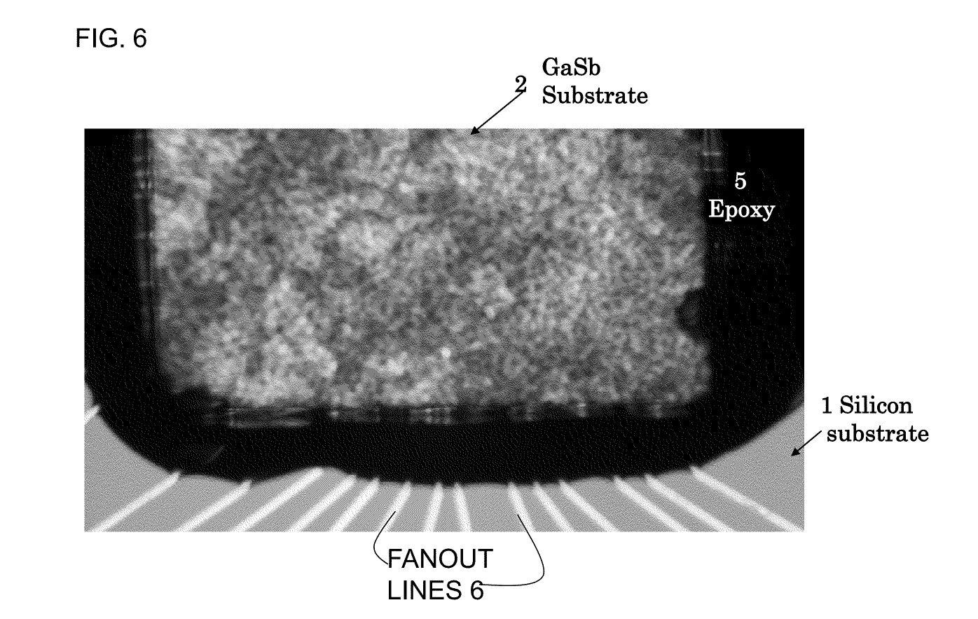

As shown schematically in FIG. 5, electrons at state Eₕ can then cross the thin AlSb barrier and GaSb layer by tunneling into the conduction band of the next injection region because of strong spatial interband coupling, and they are ready for the next interband transition, resulting in photon emission. The LED fabrication process was started with reactive ion etching of the mesa area using a Cl₂/Bcl₃ gas mixture and etching down to the bottom contact layer. The total etch depth was approximately 3.0 microns. The square mesa size of each pixel in the 6×6 array was approximately 100 μm a side. Silicon nitride was deposited by plasma-enhanced chemical vapor deposition (PECVD) at a substrate temperature of 250° C., after which contact windows were opened and a Ti/Au metal layer was deposited. After the LED array fabrication on the GaSb substrate, the array was flip-chip mounted onto a silicon fan-out array. First, indium bump was deposited on both LED and silicon fan-out arrays, and then used a thermocompression flip-chip-mount process was used to bond the devices. Epoxy 5 underfill was applied (as shown in FIG. 6), and then the array was cured at 90° C. for 1 h. The GaSb substrate was thinned by mechanical lapping from 500 μm thickness to 25 μm. The LED chip was then wire bonded and mounted on the cryostat cold finger. Light was observed from the substrate side on all flip-chip-mounted arrays. Alternatively, light emission from LED devices with top emission without flip-chip bonding may be utilized. In those cases we used a different set of masks, with a top metal opening for light to pass through. For top-emitting devices, one must first thin the GaSb substrate from the bottom side and then mount the device onto a cryostat cold finger.

### Experimental Work

Experiments were performed using an LWIR LED device with an interband cascade (IC) LED structure with 30 periods of InAs/GaInSb/AlSb type II active layers and n-type InAs/Al(In)Sb injection layers sandwiched between two p-type GaSb contact layers. For further discussion, see N. C. Das, “Performance comparison of top and bottom emitting LWIR LED devices,” J. of Electronic Material, vol. 38, 2329 (2009), hereby incorporated by reference. The total thickness of active and injection regions was 478 A° and it was designed for a peak emission of 8 μm (although a wavelength range of approximately 6-10 μm is possible) at room temperature. The active region was sandwiched between a 1.4 μm thick top p-type contact layer and a 0.4 μm-thick bottom contact layer. The advantage of using quantum cascade layers is that the recycling of carriers that occurs (i.e., the sequential transport from an active emitting region to the downstream next active region) leads to efficient photon emission. In this structure, carriers emit in principle as many photons as encountered by the active regions during their transport. The detailed band structure of the LED active/injection has been reported in N. C. Das “Effect of grating on IR LED device performance” Infared Physics and technology, 53, 71, (2010) (hereby incorporated by reference). The IC LED structure was grown by a Varian Gen-II molecular beam epitaxial machine on a (100) n-type GaSb substrate. Following removal of the native oxide at 570° C., a 0.4 p+ GaSb bottom contact layer was grown at a substrate temperature of 490° C., as measured by a thermocouple located behind the wafer. The temperature was reduced to 400° C. for growth of the active/injection regions, which consisted of InAs, AlSb, GaSb, and InGaSb layers.

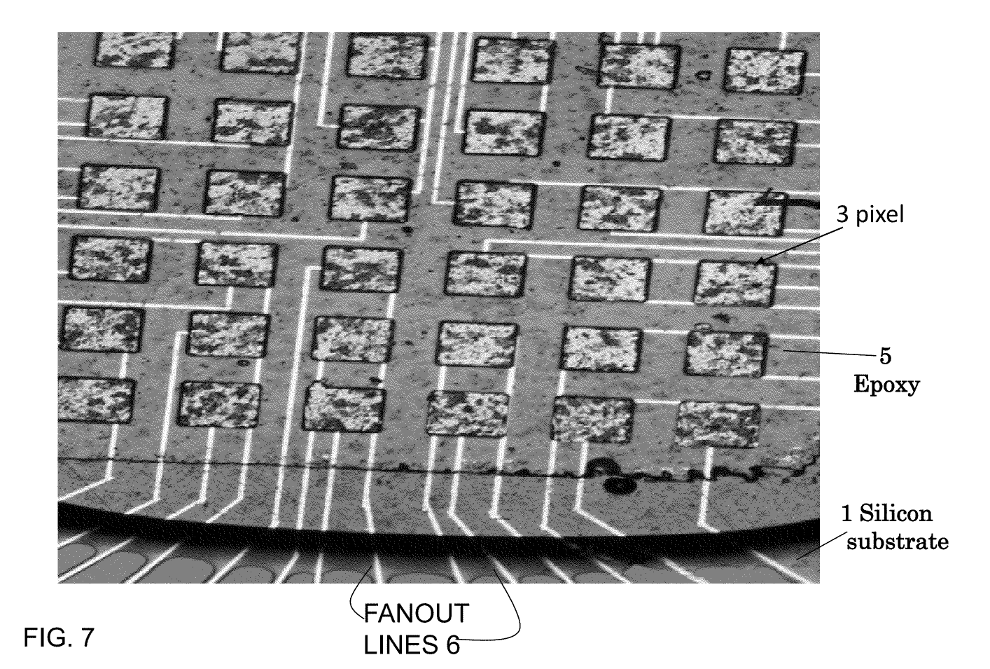

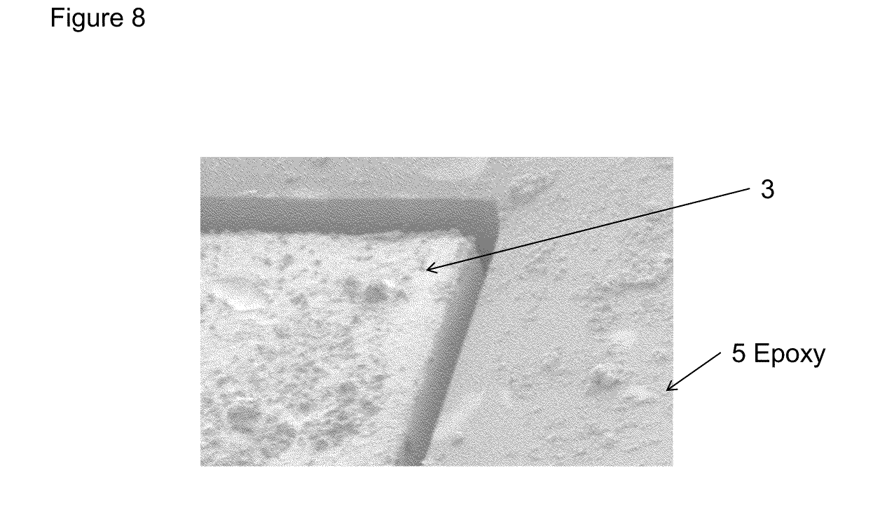

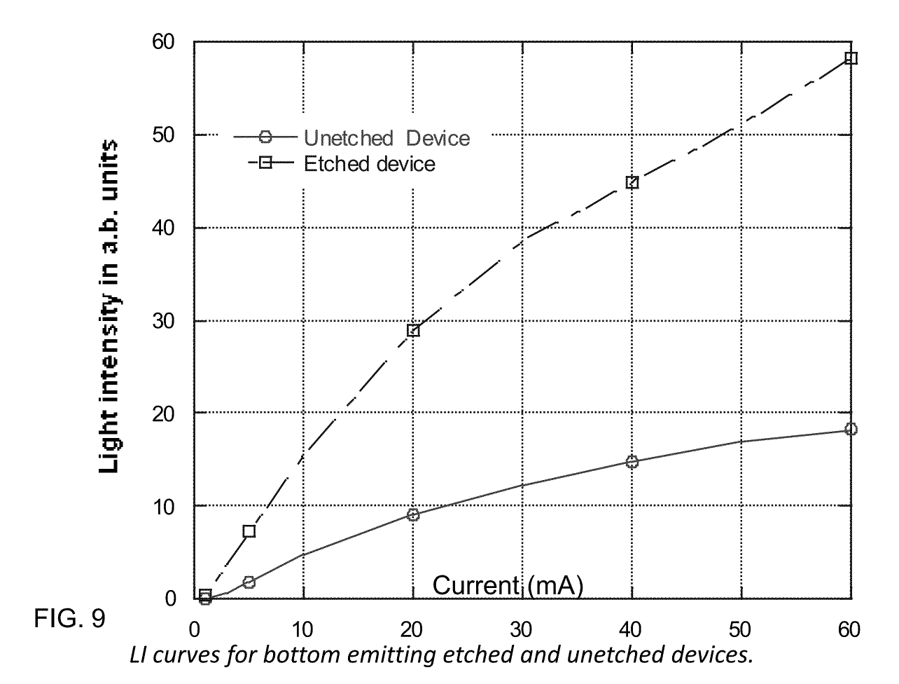

Device fabrication started with inductively coupled plasma (ICP) dry etching with mixture of Cl₂ and BCl₃ gases to define the mesa area of 100 mm². The etch depth for mesa isolation was 2.6 μm. Silicon nitride was deposited by plasma enhanced chemical vapor deposition (PECVD) technique. Contact windows were opened. Ti/Au metallization (300/3000 Ang.) was done by e-beam evaporation technique for both the top and bottom contacts. Finally deep trench etch (˜20 μm) was carried out on the top surface to isolate each device from other devices. Since these LEDs are bottom emitting devices, the devices were “flip chip” mounted on a silicon fan-out array. An indium (In) pad of 5 μm thickness was placed on both LED and fan-out sides before flip chipping the array together with the silicon fan-out array. FIG. 6 shows the bottom emitting LED device after mounting onto a fan-out array. GaSb substrate is thinned using lapping (3 micron grit alumina powder) and polishing the substrate to thin layer of 25 micron. Finally the remaining GaSb substrate is chemically etched using acetic acid, hydrogen peroxide and hydrochloric acid mixture to isolate each pixel as shown in FIG. 7. The final step of wet chemical etching was performed using periodic inspection to make sure that the devices were not over-etched. As seen in FIG. 7 the metal lines connecting various LED pixels are protected from chemical etching by the epoxy placed after flip chip bonding of LED array onto fan out array to hold them together. Each of the LED pixels has two metal lines, one for cathode and another for anode contacts. Some of the LED pixel have common cathode ground, but all have separate anode contacts. Metal lines are connected to 100 μm² metal pads (not seen in the figure) for wire bonding to be used for array testing.

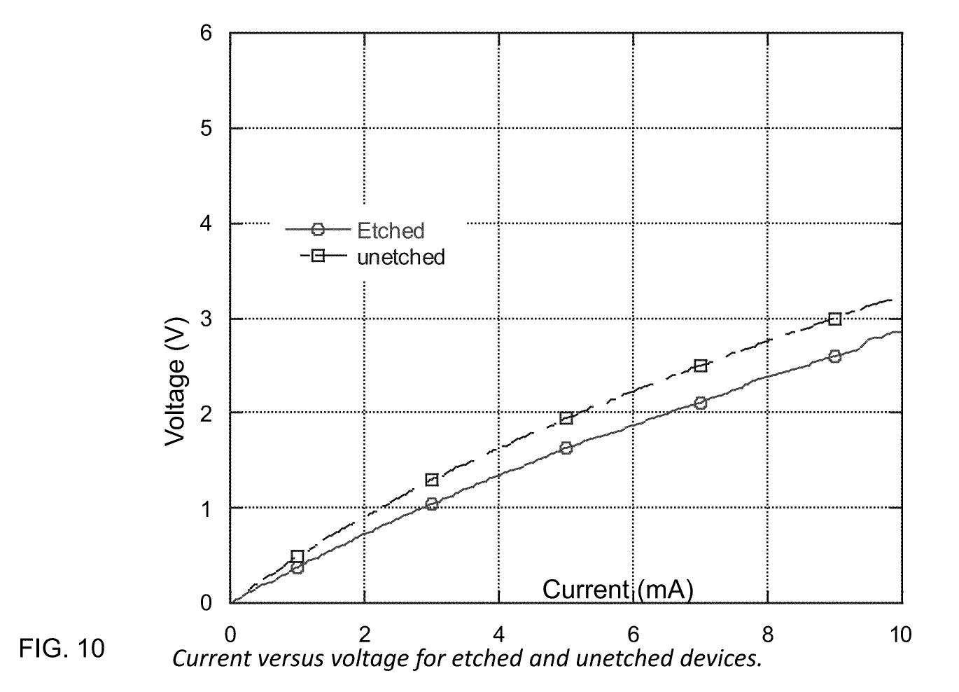

Light was collected and collimated by a 2-inch-aperture lens with a focal length of 2 inch. A one inch focal length lens was used to focus the light onto an HgCdTe detector. A pulsed current of 6 μS pulse width and 30% duty cycle was used for light emission measurement. FIG. 10 illustrates the optical output power versus LED injection current (LI) for both the devices of etched and unetched samples. The total output power increases with injection current and attains saturation at higher current values. This observation can be attributed to increased thermal leakage and other possible non-radiative carrier recombination processes that are enhanced at higher active region temperatures. For further information in this regard, see Pidgeon C R, et al., “Suppression of Non-radiative Processes in Semiconductor Mid-infrared Emitters and Detectors,” Prog Quant Electron, 21,361, (1998), hereby incorporated by reference. As seen in FIG. 10, a three-fold increase in light intensity was observed for the etched device compared to the unetched device. Also observed was a higher increase of light output for etched device at higher current than unetched device.

The current voltage (IV) curves of two devices are shown in FIG. 10. The voltage drop of the etched device is about 15% less than the unetched sample. This finding clearly indicates that heat generation due to high injection current in the etched device will be lower than the unetched device. This is a very important design factor for an LED device as it can be biased to higher current without thermal runaway. The voltage drop across the device depends on many factors such as: a) the number of active/injection regions in IC structure, b) the number of defect density in quantum well region, and c) the contact resistance of the metal electrode. Lower turn on voltage in etched device may be due to lower resistance of etched device due to thermal isolation from adjacent pixels. Though not shown here, the spectrum of light emission remains the same for both etched and unetched samples.

There exist various techniques to improve the out-coupling of IR light from high index GaSb substrate including grating (see. e.g., N. C. Das, “Effect of grating on IR LED device performance,” Infrared Physics and technology 53, 71, (2010) (hereby incorporated by reference), antireflection coating and sloped mesa structure (see, L. Vescan, et al., “Electric, Photoelectric and Optical Investigations of Semiconductor Layers and Devices,” Mater. Sci. Semicon. Proc. 3, 383, (2000) (hereby incorporated by reference). However, at the time of filing of the application, it was believed by the inventor that no one had reported the use of substrate removal and device isolation technique for improving the LWIR LED performance. The light output characteristics from LWIR LED depend on many factors, such as design and growth parameters, processing techniques, device operating temperature, device geometry carrier relaxation and radiative recombination. See, Pidgeon C R, et al., “Suppression of Non-radiative Processes in Semiconductor Mid-infrared Emitters and Detectors,” Prog Quant Electron, 21,361, (1998), hereby incorporated by reference. The measured electroluminescence power depends upon the balance of these processes. For low injection current densities (FIG. 10) the increase in output power is due to carrier injection and recombination process (see G. B. Stringfellow and M. G. Craford, High brightness LED, Semicond. Semimetal, 48, 469, (1997) (hereby incorporated by reference). At higher injection current, various non-radiative processes such as phonon relaxation become dominant and hence light output saturates and then decreases (See, A. Krier, et al., “High power 4.6 μm light emitting diodes for CO detection,” J. Appl. Phys. D 32, 3117 (1999) (hereby incorporated by reference).

In the paper N. C. Das, “Performance Comparison of Top and Bottom Emitting LWIR LED Devices, J. of Electronic Material, vol. 38, 2329, 2009, it was reported that bottom emitting LED structures have higher light output than top emitting structures. Hence, a bottom emitting structure was chosen to perform the pixel isolation experiment. The advantages of a bottom emitting device are the proximity of the quantum well to the heat sink on which the fan-out array is mounted and the ability to reflect the whole anode layer by putting metal on the top surface. A 300% increase was observed in LED optical power by thinning the GaSb substrate and isolating the pixels from surrounding device in the array. As seen in FIG. 10, the light output of the unetched sample is almost saturating at 60 mA injection current, where as the etched sample light out still continues to increase even at the 60 mA injection current. Hence the difference in output light power will be higher for the etched sample than the unetched sample at higher injection currents.

The etched sample not only gives a higher output power, but also has a low turn on voltage (FIG. 10). The low turn on voltage may be due to the less contact resistance of an isolated device structure produced after thinning the substrate. For bottom emitting structures (FIG. 6), both cathode and anode contacts are on the top of the mesa structure. Hence by isolating the device from each other, the conducting path of the heat between pixels is eliminated. We thus get enhanced light emission by isolating each pixel from the array. The fully fabricated and isolated bottom emitting LED device can be used for further improving the device performance by many other processing technologies: grating formation, antireflection coating, and lenslet formation etc.

In summary, in the experiments performed, a 300% increase in optical power from LWIR LED device was obtained by thinning the bottom substrate till each pixel is isolated from the others. The chemical etching procedure was optimized so that etching stops after all the pixels in two dimensional array are separated. By thermal isolation of bottom emitting LED devices, cross talk of light emission is eliminated.

As used herein the terminology mesa, pixel and islands are used interchangeably.

As used herein the terminology separation region and gap have substantially the same meaning and are used interchangeably.

As used herein the terminology “array” refers to a systematic arrangement of pixels in rows and columns.

Although various preferred embodiments of the present invention have been described herein in detail to provide for complete and clear disclosure, it will be appreciated by those skilled in the art, that variations may be made thereto without departing from the spirit of the invention.

It should be emphasized that the above-described embodiments are merely possible examples of implementations. Many variations and modifications may be made to the above-described embodiments. All such modifications and variations are intended to be included herein within the scope of the disclosure and protected by the following claims. The invention has been described in detail with particular reference to certain preferred embodiments thereof, but it will be understood that variations and modifications can be effected within the spirit and scope of the invention.

1. An infrared LED device comprising:
a plurality of LED mesas; each mesa separated by a gap of approximately 50 to 100 microns; each mesa being from approximately 25 to 500 microns, plurality of indium contacts, each mesa having at least two contacts associated therewith; one positive and one ground contact,
a substrate;
a plurality of leads for connection to the positive and negative contacts,
whereby upon application of electrical power infrared light emission occurs.

2. The device of claim 1 wherein the infrared LED device is a Type II superlattice which is mounted epi-side down and wherein the mesas are positioned in an array.

3. The device of claim 1 wherein each LED mesa comprises alternating cascaded active/injection regions.

4. The device of claim 3 wherein alternating cascaded active/injection regions comprise an InAs/GaInSb/ InAs ‘W’ quantum well active region preceded by n-type digitally graded InAs/Al(In)Sb injection region.

5. The device of claim 3 wherein the n-type injection regions serve as the collector and emitter for the preceding and following InAs/GaInSb/InAs ‘W’ quantum well active regions.

6. The device of claim 4 wherein the alternating active and injection regions structure is strain balanced and lattice matched to the GaSb substrate.

7. The device of claim 5 wherein under a forward bias, electrons were injected from an injection region into the Eₑ level which is in the band gap region of the adjacent GaInSb layer, and the electrons in the Eₑ level are effectively blocked from directly tunneling out of the GaInSb and Al(In)Sb layers, they tend to relax to the hole state Eh in the adjacent valence band quantum well, resulting in photon emission.

8. A method of making an infrared LED device;
providing a first substrate;
using molecular beam epitaxy, growing a quantum well structure comprising alternating active and injection regions on the substrate;
growing a thin p-type layer on the quantum well structure;
etching the mesa area down to the substrate to form a plurality of mesas, each mesa being separated by a separation region of approximately 50 to 100 microns; each mesa being from approximately 25 to 500 microns;
forming electrical contacts;
deep etching to isolate each of the mesas;
deposit first indium contacts on the upper surface of the mesas;
provide a second substrate;
forming electrically conducting lines and pads;
deposit second indium contacts on the upper surface of the gold pads;
bonding the fanout silicon substrate and the GaSb mesa structure such that first indium contacts are in contact with the second indium contacts.

9. The method of claim 8 wherein the first substrate is GaSb and the second substrate is silicon.

10. The method of claim 8 wherein the step of using molecular beam epitaxy to grow a quantum well structure comprises forming at least 30 alternating active and injection regions on the substrate, and further comprises the step of growing a 1.4 micron p-type layer on the quantum well structure.

11. The method of claim 8 wherein the step of etching the mesa area down to the substrate to form a plurality of mesas comprises etching approximately 3 microns using reactive ion etching of the mesa area using a Cl₂/Bcl₃ gas mixture and etching down to the GaSb base to form a plurality of mesas, each mesa being separated by a separation region of approximately 50 to 100 microns; each mesa being from approximately 25 to 500 microns.

12. The method of claim 9 further wherein the step of forming electrical contacts comprises:
depositing a silicon nitride layer on both the mesas and separation regions;
using photolithography to make a pattern for anode and cathode contacts;
etching the silicon nitride layer using dry etching;
depositing gold metal by electron beam evaporation technique to form the anode and cathode contacts.

13. The method of claim 8 further wherein the step of deep etching comprises deep etching 20 microns to form a trench around the mesas for mechanical stability to form a GaSb mesa structure.

14. The method of claim 8 wherein the steps of depositing the first and second indium contacts comprises depositing contacts approximately 5-10 microns.

15. The method of claim 8 wherein the step of bonding the fanout silicon substrate and the GaSb mesa structure such that first indium contacts are in contact with the second indium contacts comprises:
flip-chip bonding the fanout silicon substrate and the GaSb mesa structure such that first indium contacts are in contact with the second indium contacts;
applying epoxy in the separation regions;
curing the epoxy.

16. The method of claim 8 wherein the step of deep etching to isolate each of the mesas comprises removing a portion of the GaSb layer (up to approximately 475 microns to leave approximately 25 microns and chemical etching to isolate the mesas.

17. A method of making an infrared LED device;
providing a substrate;
using molecular beam epitaxy, growing a quantum well structure comprising alternating active and injection regions on the substrate;
growing a thin p-type layer on the quantum well structure;
etching the mesa area down to the substrate to form a plurality of mesas, each mesa being separated by a separation region of approximately 50 to 100 microns; each mesa being from approximately 25 to 500 microns;
using photolithography to make a pattern for anode and cathode contacts;
etching the silicon nitride layer using dry etching;
depositing gold metal by electron beam evaporation technique to form the anode and cathode contacts;
deep etching (approximately 20 microns) to form a trench around the mesas for mechanical stability to form a GaSb mesa structure;
deposit first indium contacts (approximately 5-10 microns) on the upper surface of the mesas;
provide a silicon substrate;
deposit silicon dioxide on the substrate;
using a photolithographic technique, depositing gold metal to form gold metal lines and pads;
deposit second indium contacts (approximately 5-10 microns) on the upper surface of the gold pads;
flip-chip bonding the fanout silicon substrate and the GaSb mesa structure such that first indium contacts are in contact with the second indium contacts;
applying epoxy in the separation regions;
curing the epoxy at approximately 70 to 100 degrees Celsius for one to two hours;
removing a portion of the GaSb layer (up to approximately 475 microns to leave approximately 25 microns;
chemical etching the remaining 25 microns to isolate the mesas.
